(19) United States
(12) Patent Application Publication
(10) Pub. No.: US 2019/0040887 A1
(43) Pub. Date: Feb. 7, 2019

(54) FIXING STRUCTURE FOR METAL PLATE AND SYNTHETIC RESIN MATERIAL, AND WIRING MEMBER INCLUDING THE SAME

(71) Applicants: AUTONETWORKS TECHNOLOGIES, LTD., Yokkaichi, Mie (JP); SUMITOMO WIRING SYSTEMS, LTD., Yokkaichi, Mie (JP); SUMITOMO ELECTRIC INDUSTRIES, LTD., Osaka-shi, Osaka (JP)

(72) Inventors: Taiji YANAGIDA, Yokkaichi-shi, Mie (JP); Shinichi TAKASE, Yokkaichi-shi, Mie (JP); Nobuyuki MATSUMURA, Yokkaichi-shi, Mie (JP)

(21) Appl. No.: 16/073,158

(22) PCT Filed: Jan. 20, 2017
(86) PCT No.: PCT/JP2017/001867

§ 371 Date: Jul. 26, 2018

(30) Foreign Application Priority Data
Feb. 2, 2016 (JP) 2016-017761

(51) Int. Cl. F16B 4/00; F16B 5/00; H01R 4/18; H05K 7/02; H01R 43/048

(52) U.S. Cl. CPC F16B 4/004; F16B 5/00; H01R 43/048; H05K 7/02; H01R 4/18

(57) ABSTRACT

A fixing structure for a metal plate and a synthetic resin material, the metal plate having a bottom wall, and a first crimp piece and a second crimp piece that respectively extend from opposite side edges of the bottom wall and are crimped so as to wind around the synthetic resin material. In the synthetic resin material, a first crimped portion and a second crimped portion constituted by opposite side edges of the synthetic resin material being depressed are formed. The first crimp piece is crimped to the first crimped portion, and the second crimp piece is crimped to the second crimped portion.

### CROSS REFERENCE TO RELATED APPLICATIONS

This application claims the priority of Japanese patent application JP2016-017761 filed on Feb. 2, 2016, the entire contents of which are incorporated herein.

### TECHNICAL FIELD

The technology disclosed herein relates to a fixing structure for a metal plate and a synthetic resin material, and to a wiring member including the same.

### BACKGROUND ART

Conventionally, as a fixing structure for metal plates and synthetic resin materials, a fixing structure using bolts and a fixing structure using adhesive are known. Of these, the fixing structure using bolts is disclosed in Japanese Patent No. 5399802.

### SUMMARY

However, the fixing structure using bolts requires a configuration for suppressing loosening due to stress relaxation of the synthetic resin material. Furthermore, the shaft portions of the bolts are configured to protrude. The use of bolts thus poses a problem in that it is difficult to reduce the size of the fixing structure.

Also, the fixing structure using adhesive additionally requires a structure for suppressing positional shift, separation following degradation of the adhesive and the like, which poses a problem in that it is again difficult to reduce the size of the fixing structure.

The technology disclosed herein was arrived at based on the above-described circumstances, and an object thereof is to reduce the size of a fixing structure for a metal plate and a synthetic resin material.

The technology disclosed herein is a fixing structure for a metal plate and a synthetic resin material, the metal plate having a bottom wall and a crimp piece that extends from a side edge of the bottom wall and is crimped so as to wind around the synthetic resin material, and a recessed portion formed in the synthetic resin material serving as a crimped portion, with the crimp piece being crimped to the crimped portion.

With the above-described configuration, it is possible to fix the metal plate and the synthetic resin material with a simple technique involving crimping the crimp piece to the crimped portion. Since the crimp piece is crimped so as to wind around the synthetic resin material, the protruding dimension from the synthetic resin material is small compared with a fixing structure using bolts. Accordingly, it is possible to reduce the size of the fixing structure. In addition, the fixing structure can be reduced in size compared with a fixing structure using adhesive, since a configuration for suppressing positional shift, separation following degradation of the adhesive and the like is not necessary.

The following modes are preferable as embodiments of the technology disclosed herein.

It is preferable that the crimp piece is crimp pieces respectively extending from opposite side edges of the bottom wall, and the crimp pieces are crimped to the crimped portion of the synthetic resin material such that distal end edges of the crimp pieces are opposed to each other.

With the above-described configuration, the metal plate can be crimped to the synthetic resin material using a uniform force. This makes it possible to improve the fixing strength between the metal plate and the synthetic resin material.

It is preferable that the crimped portion is constituted by opposite side edges of the synthetic resin material being depressed, and Expressions (1) and (2) below are satisfied:

PW1<MW3<PW1+PD1+PD2 (1)

MH1=MH2 (2)

where PD1 is a depression depth dimension of the crimped portion, among the crimped portions, that is formed at one side edge of the synthetic resin material, from the side edge of the synthetic resin material, PD2 is a depression depth dimension of the crimped portion, among the crimped portions, that is formed at the other side edge of the synthetic resin material, from the side edge of the synthetic resin material, PW1 is a width dimension of a region of the synthetic resin material that is sandwiched between the crimped portions, MH1 is an extension height dimension of the crimp piece, among the crimp pieces, that is formed at one side edge of the bottom wall, from the one side edge of the bottom wall, and MH2 is an extension height dimension of the crimp piece formed at the other side edge of the bottom wall, from the other side edge of the bottom wall, MW1 is a width dimension of the crimp piece, among the crimp pieces, that is formed at one side edge of the bottom wall, in a direction intersecting a direction extending from the one side edge of the bottom wall, MW2 is a width dimension of the crimp piece formed at the other side edge of the bottom wall, in a direction intersecting a direction extending from the other side edge of the bottom wall, and MW3 is a width dimension of the bottom wall.

By setting PW1<MW3, it is possible to achieve the effect of being able to install the synthetic resin material so as not catch on the crimp pieces. By setting MW3<PW1+PD1+PD2, it is possible to achieve the effect of temporarily holding the synthetic resin material at the desired position during crimping, and preventing detachment of the synthetic resin material after crimping. By setting MH1=MH2, it is possible to achieve the effect of preventing the crimp pieces from rotating and deforming by uniformly pressing the crimp pieces during crimping, and also preventing the synthetic resin material from detaching as a result of torsional deformation in the presence of tension by pressing the synthetic resin material symmetrically with respect to the center after crimping, thereby enhancing tensile strength.

It is preferable to satisfy Expression (3) below:

0.8≤H/(T1+T2×2)≤1.5 (3)

where T1 is a thickness dimension of the synthetic resin material, T2 is a thickness dimension of the metal plate, and H is a maximum height dimension from a bottom face of the bottom wall to the crimp pieces in a state in which the crimp pieces are crimped to the crimped portions.

With the above-described configuration, the fixing strength between the metal plate and the synthetic resin material can be improved.

Since the fixing strength between the metal plate 10 and the synthetic resin material 11 can be further improved, it is preferable to satisfy Expression (4) below:

0.8≤H/(T1+T2×2)≤1.3 (4)

Since the fixing strength between the metal plate and the synthetic resin material can be still further improved, it is particularly preferable to satisfy Expression (5) below:

0.8≤H/(T1+T2×2)≤1.2 (5)

Also, the fixing structure for a metal plate and a synthetic resin material according to the technology disclosed herein can be suitably applied to a wiring member including a metal plate that is to be connected to an electrical device.

According to the technology disclosed herein, it is possible to reduce the size of a fixing structure for a metal plate and a synthetic resin material.

### BRIEF DESCRIPTION OF DRAWINGS

FIG. 1 is a partially enlarged plan view of a fixing structure for a metal plate and a synthetic resin material according to Embodiment 1, showing a state before a first crimp piece and a second crimp piece of the metal plate are crimped to the synthetic resin material.

FIG. 2 is a cross-sectional view taken along the line II-II in FIG. 1.

FIG. 3 is a partially enlarged plan view showing the fixing structure for a metal plate and a synthetic resin material.

FIG. 4 is a cross-sectional view taken along the line IV-IV in FIG. 3.

FIG. 5 is a plan view showing a test piece used in a model experiment.

FIG. 6 is an enlarged plan view showing relevant portions of the test piece.

FIG. 7 is a plan view showing a synthetic resin material related to the test piece.

FIG. 8 is a plan view showing a metal plate related to the test piece.

FIG. 9 is a partially enlarged plan view showing the metal plate related to the test piece.

FIG. 10 is a partially enlarged side view showing the metal plate related to the test piece.

FIG. 11 is a partially enlarged front view showing the metal plate related to the test piece.

FIG. 12 is a graph showing a change in fixing strength against H/(T1+T2×2).

### DESCRIPTION OF EMBODIMENTS

### Embodiment 1

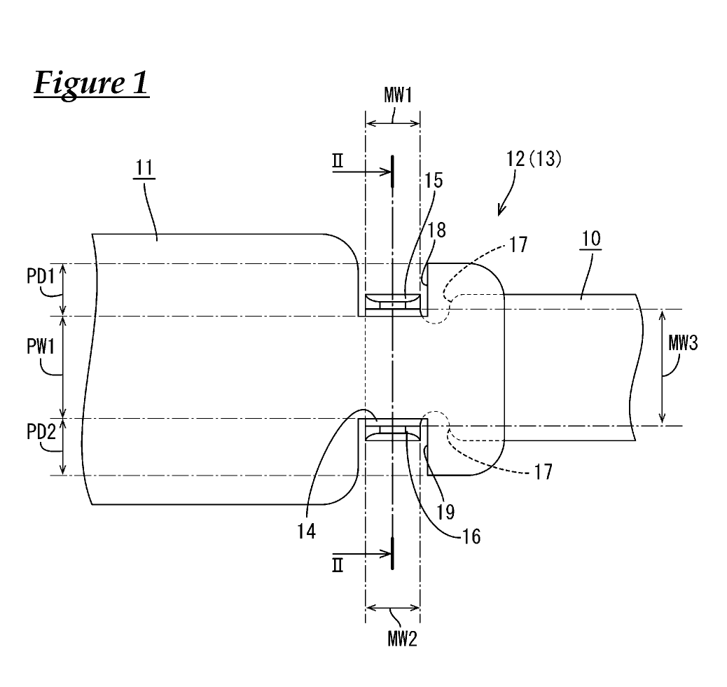

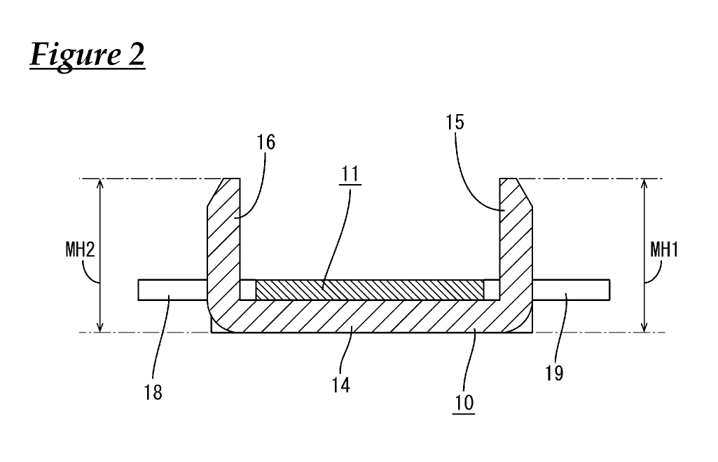

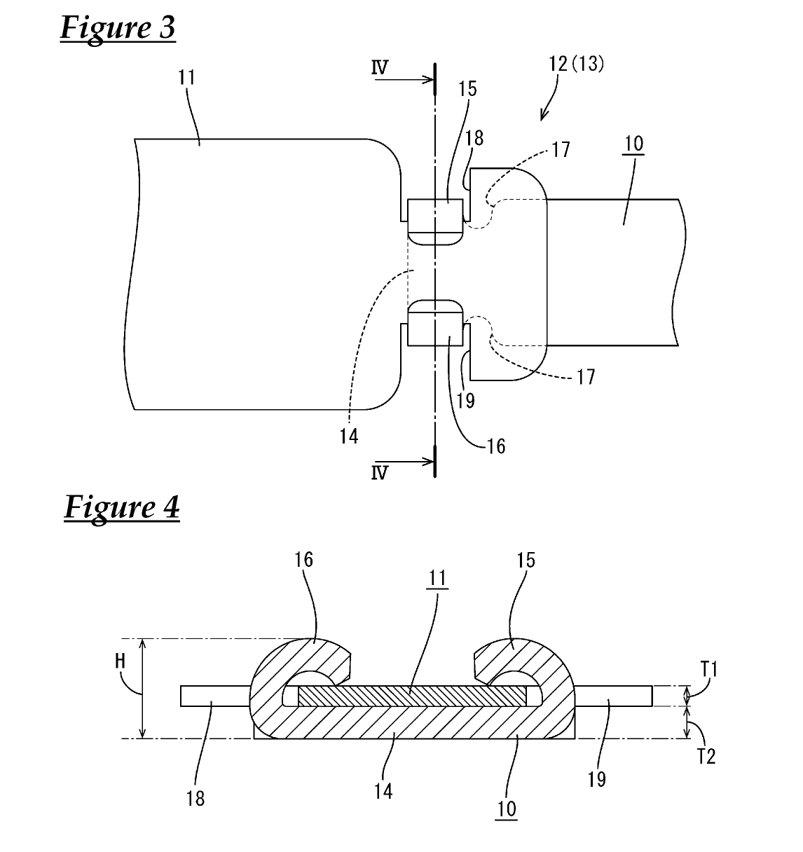

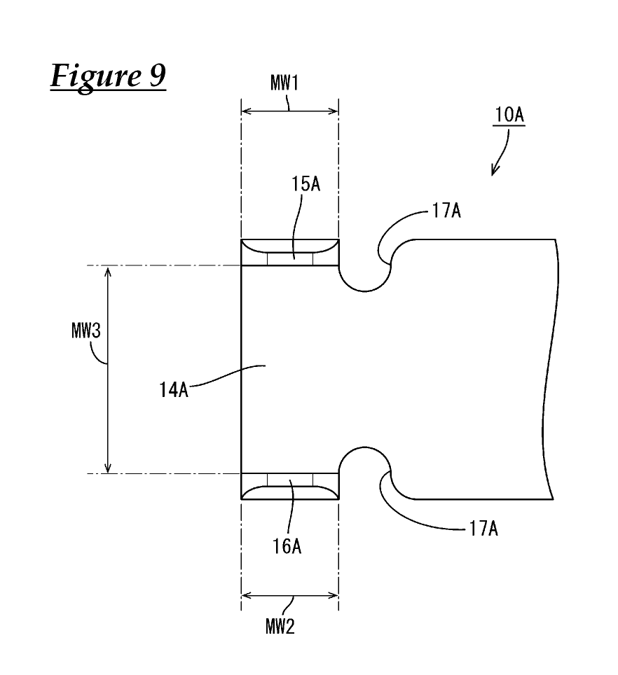

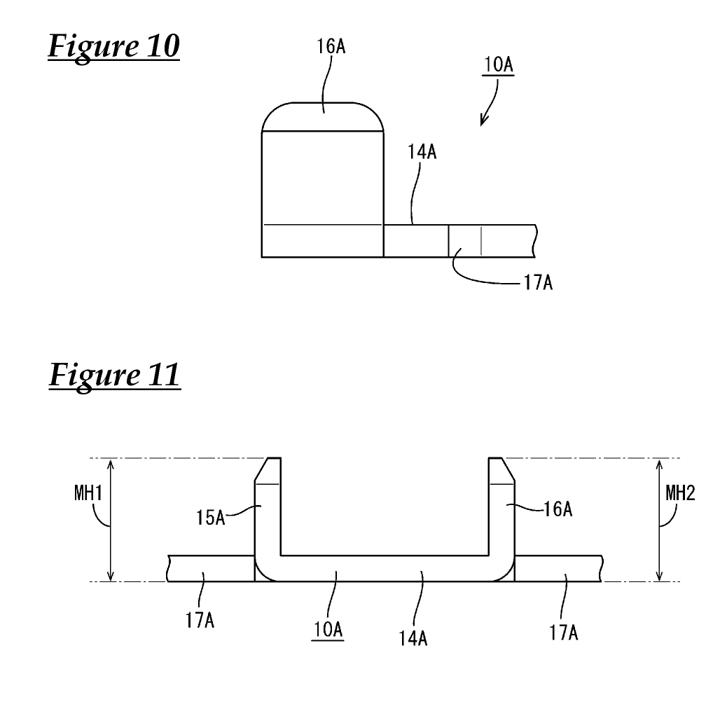

Embodiment 1 of the technology disclosed herein will be described with reference to FIGS. 1 to 12. The present embodiment relates to a fixing structure 12 for a metal plate 10 and a synthetic resin material 11. The metal plate 10 is assumed to be a wiring member 13 connected to an electrical device (not shown).

As the metal constituting the metal plate 10, any metal such as iron, an iron alloy, copper, a copper alloy, aluminum, and an aluminum alloy may be appropriately selected as needed. A plated layer may be formed on the surface of the metal plate 10. As the metal constituting the plated layer, any metal such as tin, solder and nickel may be appropriately selected as needed. The metal plate 10 is worked into a predetermined shape by press working or the like.

The metal plate 10 includes a bottom wall 14 extending in an elongated manner. A first crimp piece 15 (an example of the crimp pieces) and a second crimp piece 16 (an example of the crimp pieces) that protrude outwardly are formed at two side edges in the extension direction of the bottom wall 14 at positions located toward a distal end portion of the bottom wall 14. The first crimp piece 15 and the second crimp piece 16 have the same shape. In the present embodiment, the first crimp piece 15 and the second crimp piece 16 extend in a direction substantially orthogonal to the wall surface of the bottom wall 14 in a stage before they are crimped to the synthetic resin material 11.

In the metal plate 10, two recessed portions 17 constituted by opposite side edges of the bottom wall 14 being depressed are formed at positions opposite to the distal end portion of the bottom wall 14 so as to correspond to the first crimp piece 15 and the second crimp piece 16, respectively. The two recessed portions 17 have the same shape.

Examples of the synthetic resin material 11 include a plate material, a sheet material and a film made of a synthetic resin. As the synthetic resin constituting the synthetic resin material 11, any synthetic resin including, for example, polyolefins such as polyethylene and polypropylene, polyesters such as polyethylene terephthalate and polybutylene terephthalate, polyamides such as nylon 6 and nylon 6,6, polystyrene, and polycarbonate may be appropriately selected as needed.

The synthetic resin material 11 may be insulating or may be conductive. When the synthetic resin material 11 is insulating, the metal plate 10 connected to the electrical device is insulated by the synthetic resin material 11. On the other hand, when the synthetic resin material 11 is conductive, the metal plate 10 and the synthetic resin material 11 serve as conductive members.

The synthetic resin material 11 is formed in a sheet shape extending in an elongated manner. A first crimped portion 18 (an example of the crimped portions) and a second crimped portion 19 (an example of the crimped portions) that are depressed in the width direction of the synthetic resin material 11 are respectively formed at two side edges in the extension direction of the synthetic resin material 11 at positions located toward an end portion of the synthetic resin material 11. The first crimped portion 18 and the second crimped portion 19 have the same shape. The first crimped portion 18 and the second crimped portion 19 correspond to the recessed portions formed on the synthetic resin material 11.

The first crimp piece 15 and the second crimp piece 16 are crimped to the first crimped portion 18 and the second crimped portion 19, respectively, so as to wind around the synthetic resin material 11. The first crimp piece 15 and the second crimp piece 16 are crimped such that their distal end portions are opposed to each other. The distal end portions of the first crimp piece 15 and the second crimp piece 16 are in abutment against the surface of the synthetic resin material 11. On the other hand, the distal end portion of the first crimp piece 15 and the distal end portion of the second crimp piece 16 are spaced apart.

Of the first crimped portion 18 and the second crimped portion 19, inner wall surfaces located on the distal end portion side of the synthetic resin material 11 are configured to come into abutment against the first crimp piece 15 and the second crimp piece 16, respectively, thereby inhibiting the first crimp piece 15 and the second crimp piece 16 from being removed to the distal end portion side of the synthetic resin material 11.

### Dimensions

The respective dimensions satisfy Expressions (1) and (2) below:

PW1<MW3<PW1+PD1+PD2 (1)

MH1=MH2 (2)

where PD1 is the depression depth dimension of the first crimped portion 18 from the side edge of the synthetic resin material 11, PD2 is the depression depth dimension of the second crimped portion 19 from the side edge of the synthetic resin material 11, PW1 is the width dimension of a region of the synthetic resin material 11 that is sandwiched between the first crimped portion 18 and the second crimped portion 19, MH1 is the extension height dimension of the first crimp piece 15 from the side edge of the bottom wall 14, MH2 is the extension height dimension of the second crimp piece 16 from the side edge of the bottom wall 14, MW1 is the width dimension of the first crimp piece 15 in a direction intersecting a direction extending from the side edge of the bottom wall 14, MW2 is the width dimension of the second crimp piece 16 in a direction intersecting a direction extending from the side edge of the bottom wall 14, and MW3 is the width dimension of the bottom wall 14 of the metal plate 10.

By setting PW1<MW3, it is possible to achieve the effect of being able to install the synthetic resin material 11 so as not catch on the first crimp piece 15 and the second crimp piece 16.

By setting MW3<PW1+PD1+PD2, it is possible to achieve the effect of temporarily holding the synthetic resin material 11 at the desired position during crimping, and preventing detachment of the synthetic resin material 11 after crimping.

By setting MH1=MH2, it is possible to achieve the effect of preventing the first crimp piece 15 and the second crimp piece 16 from rotating and deforming by uniformly pressing the first crimp piece 15 and the second crimp piece 16 during crimping, and also preventing the synthetic resin material 11 from detaching as a result of torsional deformation in the presence of tension by pressing the synthetic resin material 11 symmetrically with respect to the center after crimping, thereby enhancing tensile strength.

Expression (3) below is satisfied:

0.8≤H/(T1+T2×2)≤1.5 (3)

where T1 is the thickness dimension of the synthetic resin material 11, T2 is the thickness dimension of the metal plate 10, and H is the maximum height dimension from the bottom face of the bottom wall 14 to the first crimp piece 15 and the second crimp piece 16 in a state in which the first crimp piece 15 is crimped to the first crimped portion 18 and the second crimp piece 16 is crimped to the second crimped portion 19.

By satisfying Expression (3), it is possible to improve the fixing strength between the metal plate 10 and the synthetic resin material 11.

Furthermore, since the fixing strength between the metal plate 10 and the synthetic resin material 11 can be further improved, it is preferable to satisfy Expression (4) below:

0.8≤H/(T1+T2×2)≤1.3 (4)

Furthermore, since the fixing strength between the metal plate 10 and the synthetic resin material 11 can be still further improved, it is particularly preferable to satisfy Expression (5) below:

0.8≤H/(T1+T2×2)≤1.2 (5)

### Fixing Method

The metal plate 10 and the synthetic resin material 11 can be fixed by the following procedure. Note that the fixing method for the metal plate 10 and the synthetic resin material 11 is not limited to the following description.

The synthetic resin material 11 is formed into a predetermined shape by injection molding, press working, or extension.

The metal plate 10 is formed into a predetermined shape by press working.

The synthetic resin material 11 is placed on the bottom wall 14 of the metal plate 10. At this time, the metal plate 10 and the synthetic resin material 11 are disposed such that the first crimp piece 15 and the second crimp piece 16 of the metal plate 10 are housed inside the first crimped portion 18 and the second crimped portion 19, respectively, of the synthetic resin material 11.

Subsequently, the first crimp piece 15 and the second crimp piece 16 of the metal plate 10 are crimped to the synthetic resin material 11. This process can be automated by applying pressure from above and below using a pair of molds.

### Actions and Effects of the Embodiment

Next, actions and effects of the present embodiment will be described. The present embodiment is directed to a fixing structure 12 for a metal plate 10 and a synthetic resin material 11, the metal plate 10 including a bottom wall 14 and a crimp piece that extends from a side edge of the bottom wall 14 and is crimped so as to wind around the synthetic resin material 11, and the crimp piece is crimped to a crimped portion formed by the synthetic resin material 11 being pinched.

With the above-described configuration, it is possible to fix the metal plate 10 and the synthetic resin material 11 by a simple technique involving crimping the first crimp piece 15 and the second crimp piece 16 to the first crimped portion 18 and the second crimped portion 19, respectively. Since the first crimp piece 15 and the second crimp piece 16 are crimped so as to wind around the synthetic resin material 11, the protruding dimension from the synthetic resin material 11 is small compared with a fixing structure 12 using bolts. Accordingly, it is possible to reduce the size of the fixing structure 12. In addition, the fixing structure 12 can be reduced in size compared with a fixing structure using adhesive, since a configuration for suppressing positional shift, separation due to degradation of the adhesive and the like is not necessary.

According to the present embodiment, the crimp piece is the first crimp piece 15 and the second crimp piece 16 extending from opposite side edges of the bottom wall 14, and the first crimp piece 15 and the second crimp piece 16 are crimped to the first crimped portion 18 and the second crimped portion 19, respectively, of the synthetic resin material 11 such that the distal end edge of the first crimp piece 15 and the distal end edge of the second crimp piece 16 are opposed to each other.

With the above-described configuration, the metal plate 10 can be crimped to the synthetic resin material 11 using a uniform force. This makes it possible to improve the fixing strength between the metal plate 10 and the synthetic resin material 11.

According to the present embodiment, the crimped portion is the first crimped portion 18 and the second crimped portion 19 constituted by opposite side edges of the synthetic resin material 11 being depressed, and Expressions (1) and (2) below are satisfied:

PW1<MW3<PW1+PD1+PD2 (1)

MH1=MH2 (2)

where PD1 is the depression depth dimension of the first crimped portion 18 from the side edge of the synthetic resin material 1, PD2 is the depression depth dimension of the second crimped portion 19 from the side edge of the synthetic resin material 11, PW1 is the width dimension of a region of the synthetic resin material 11 that is sandwiched between the first crimped portion 18 and the second crimped portion 19, MH1 is the extension height dimension of the first crimp piece 15 from the side edge of the bottom wall 14, MH2 is the extension height dimension of the second crimp piece 16 from the side edge of the bottom wall 14, MW1 is the width dimension of the first crimp piece 15 in a direction intersecting a direction extending from the side edge of the bottom wall 14, MW2 is the width dimension of the second crimp piece 16 in a direction intersecting a direction extending from the side edge of the bottom wall 14, and MW3 is the width dimension of the bottom wall 14.

By setting PW1<MW3, it is possible to achieve the the effect of being able to install the synthetic resin material 11 so as not catch on the first crimp piece 15 and the second crimp piece 16.

By setting MW3<PW1+PD1+PD2, it is possible to achieve the effect of temporarily holding the synthetic resin material 11 at a desired position during crimping, and preventing detachment of the synthetic resin material 11 after crimping.

By setting MH1=MH2, it is possible to achieve the effect of preventing the first crimp piece 15 and the second crimp piece 16 from rotating and deforming by uniformly pressing the first crimp piece 15 and the second crimp piece 16 during crimping, and also preventing the synthetic resin material 11 from detaching as a result of torsional deformation in the presence of tension by pressing the synthetic resin material 11 symmetrically with respect to the center after crimping, thereby enhancing tensile strength.

According to the present embodiment, Expression (3) below is satisfied:

0.8≤H/(T1+T2×2)≤1.5 (3)

where T1 is the thickness dimension of the synthetic resin material 11, T2 is the thickness dimension of the metal plate 10, and H is the maximum height dimension (crimping height) from the bottom face of the bottom wall 14 to the first crimp piece 15 or the second crimp piece 16 in a state in which the first crimp piece 15 is crimped to the first crimped portion 18 and the second crimp piece 16 is crimped to the second crimped portion 19.

With the above-described configuration, it is possible to improve the fixing strength between the metal plate 10 and the synthetic resin material 11.

Since the fixing strength between the metal plate 10 and the synthetic resin material 11 can be further improved, it is preferable to satisfy Expression (4) below:

0.8≤H/(T1+T2×2)≤1.3 (4)

Since the fixing strength between the metal plate 10 and the synthetic resin material 11 can be still further improved, it is particularly preferable to satisfy Expression (5) below:

0.8≤H/(T1+T2×2)≤1.2 (5)

The present embodiment can be suitably applied to a wiring member 13 including a metal plate 10 that is to be connected to an electrical device.

### Experimental Example

Next, the results of model experiments for confirming the effects of the technology disclosed herein will be described. Tensile testing was carried out using a test piece 22 described below.

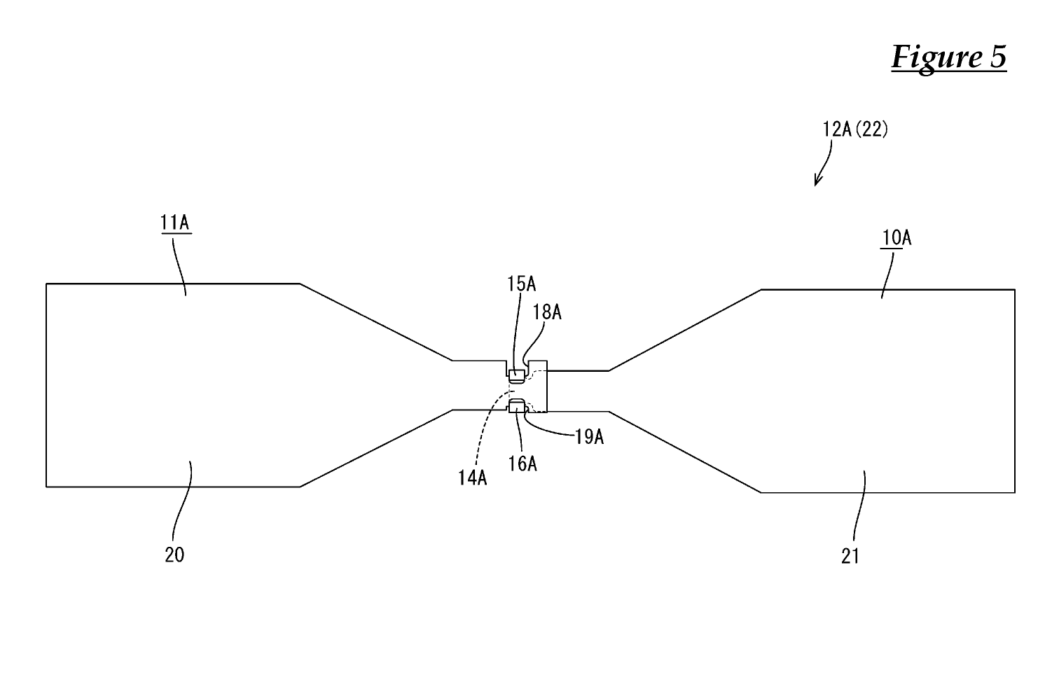

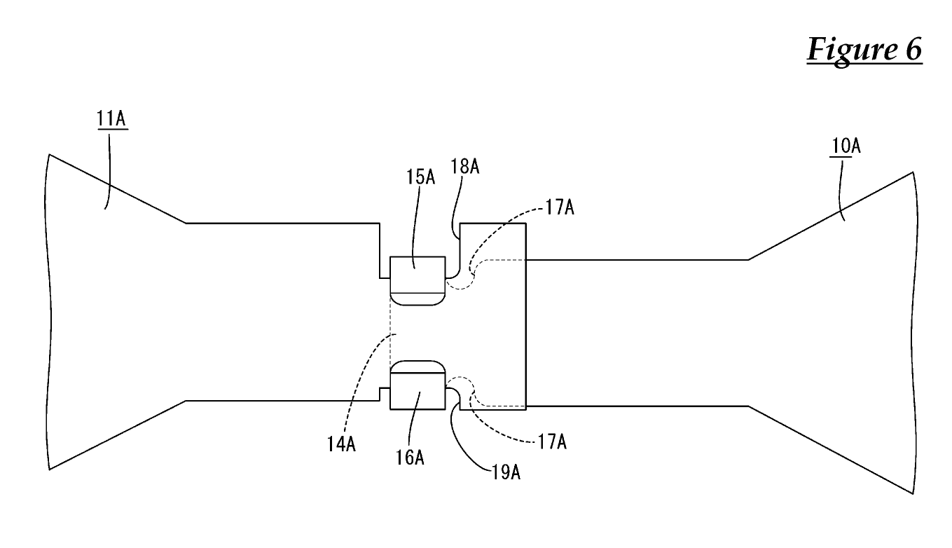

As shown in FIG. 5, tensile testing was carried out using a substantially dumbbell-shaped test piece 22. As shown in FIG. 6, a first crimp piece 15A formed on a metal plate 10A is crimped to a first crimped portion 18A formed on a synthetic resin material 11A, and a second crimp piece 16A formed on the metal plate 10A is crimped to a second crimped portion 19A formed on the synthetic resin material 11A.

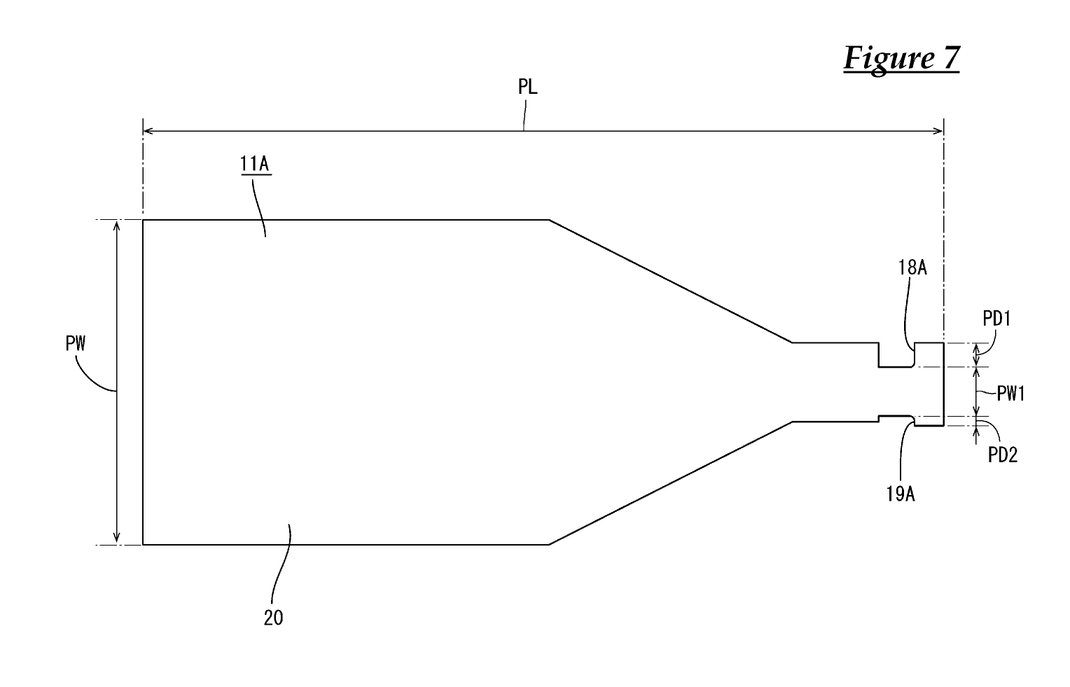

FIG. 7 shows a portion of the test piece 22 that is related to the synthetic resin material 11A. The synthetic resin material 11A is formed of polyethylene terephthalate. The synthetic resin material 11A includes a gripping portion 20 that is gripped by a tensile tester. The width dimension PW of the gripping portion 20 is 20 mm. The length dimension PL of a portion of the test piece 22 that is related to the synthetic resin material 11A is 49.3 mm.

The thickness dimension T1 of a portion of the test piece 22 that is related to the synthetic resin material 11A is 0.25 mm. PD1 of a portion of the test piece 22 that is related to the synthetic resin material 11A is 1.5 mm, and PD2 thereof is 0.6 mm. In the test piece 22, the first crimped portion 18A and the second crimped portion 19A differ from each other in their depression depth dimensions from the side edges of the test piece 22.

PW1 of the synthetic resin material 11A of the test piece 22 is 3.0 mm.

The length dimension PL1 from a distal end portion of the synthetic resin material 11A of the test piece 22 to the first crimped portion 18A and the second crimped portion 19A is 1.8 mm.

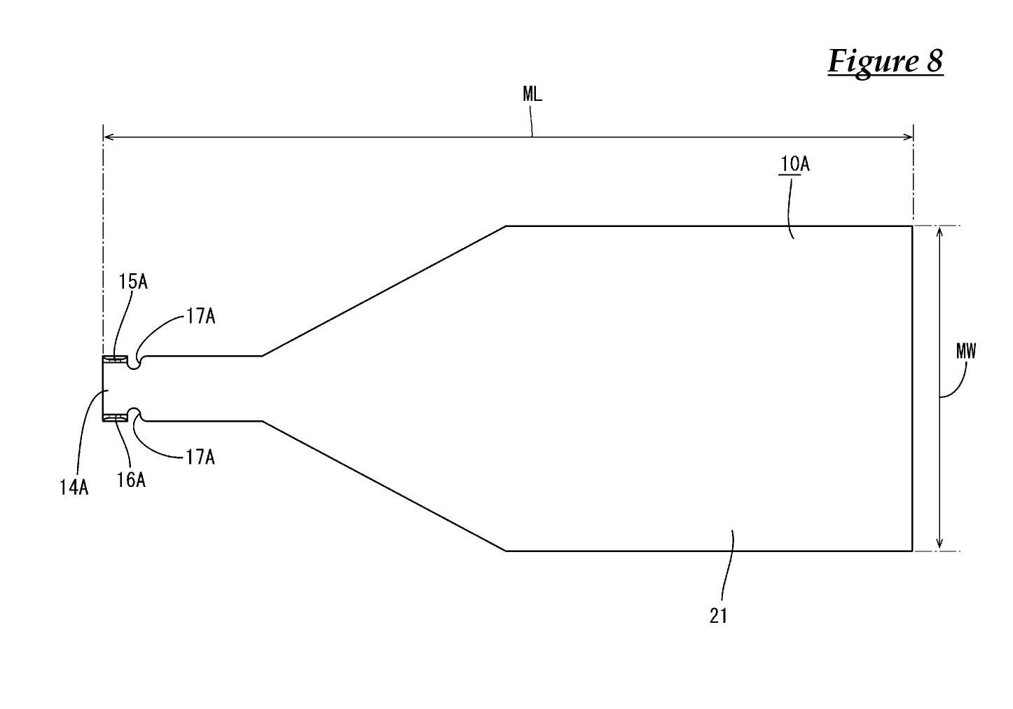

FIG. 8 shows a portion of the test piece 22 that is related to the metal plate 10A. The metal plate 10A is formed of a copper alloy. The metal plate 10A includes a gripping portion 21 that is gripped by the tensile tester. The width dimension MW of the gripping portion 21 is 20 mm. The length dimension ML of the metal plate 10A related to the test piece 22 is 49.8 mm.

The thickness dimension T2 of the metal plate 10A related to the test piece 22 is 0.4 mm. The first crimp piece 15A and the second crimp piece 16A of the metal plate 10A related to the test piece 22 are configured to have the same shape. MW1 and MW2 of the metal plate 10A related to the test piece 22 are 1.5 mm. MW3 of the metal plate 10A related to the test piece 22 is 3.2 mm. MH1 and MH2 of the metal plate 10A related to the test piece 22 are 1.9 mm. The tolerance of MH1 and MH2 is ±0.05 mm.

A dumbbell-shaped test piece 22 was produced using the metal plate 10A related to the test piece 22 and the synthetic resin material 11A related to the test piece 22 by crimping the first crimp piece 15A and the second crimp piece 16A of the metal plate 10A to the first crimped portion 18A and the second crimped portion 19A, respectively.

At this time, a plurality of test pieces 22 were produced by varying the value of the maximum height dimension (crimping height) H from the bottom face of the bottom wall 14A to the first crimp piece 15A and the second crimp piece 16A in a state in which the first crimp piece 15A and the second crimp piece 16A were crimped to the first crimped portion 18A and the second crimped portion 19A, respectively.

For the test pieces 22 produced in the above-described manner, tensile testing was carried out in accordance with JIS K7161 as follows.

The tensile speed was 50 mm/min. As the tester, MODEL 1605N manufactured by Aikoh Engineering Co., Ltd. was used. As the load cell, MODEL 3050 manufactured by Aikoh Engineering Co., Ltd. was used.

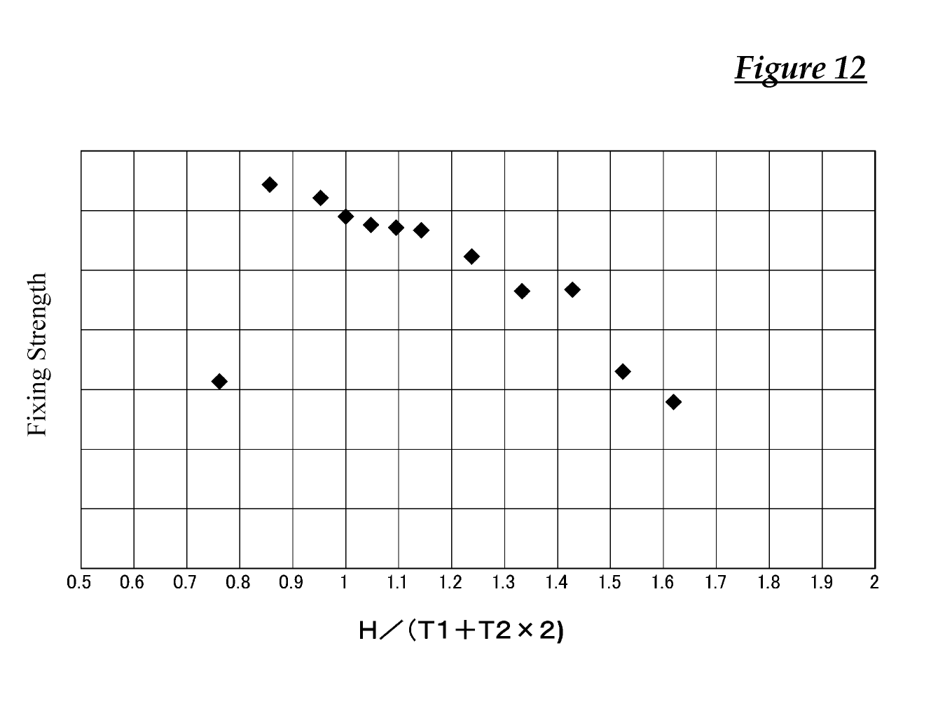

Tensile testing was carried out, and the fixing strength was calculated from the stress applied when the crimped portions between the metal plate 10A and the synthetic resin material 11A were broken. The test results are shown in FIG. 12.

FIG. 12 shows the change in fixing strength against H/(T1+T2×2). H/(T1+T2×2) is the value of ratio of the crimping height H to the sum of the thickness dimension T1 of the synthetic resin material 11A and twice the thickness dimension T2 of the metal plate 10A. The reason that the thickness dimension T2 of the metal plate 10A is doubled is to take into consideration the influence of the portion of the bottom wall 14A and the portion of the first crimp piece 15A or the second crimp piece 16A.

It is preferable that H/(T1+T2×2) is 0.8 or more because this improves the fixing strength. It is also preferable that H/(T1+T2×2) is 1.5 or less because this improves the fixing strength.

It is preferable that H/(T1+T2×2) is 1.3 or less because this further improves the fixing strength.

It is particularly preferable that H/(T1+T2×2) is 1.2 or less because this still further improves the fixing strength.

### OTHER EMBODIMENTS

The technology disclosed herein is not limited to the embodiment illustrated by the above description and drawings, and, for example, the following embodiments also fall within the technical scope of the technology disclosed herein.

The technology disclosed herein can be applied as needed to any electrical device such as a motor, an inverter, an ECU (Electronic Control Unit), and an electrical junction box.

It is also possible to adopt a configuration in which an electric wire is connected to the metal plate 10. The metal plate 10 and the electric wire may be connected by any technology such as soldering, welding, and crimping.

It is also possible to adopt a configuration in which the metal plate 10 is not connected to an electrical device.

In the present embodiment, the metal plate 10 has a configuration including the first crimp piece 15 and the second crimp piece 16. However, the metal plate 10 is not limited to this configuration, and may have a configuration including one crimp piece, or may have a configuration including three or more crimp pieces. To response thereto, the synthetic resin material 11 may have a configuration including one crimped portion, or may have a configuration including three or more crimped portions.

It is also possible to adopt a configuration in which the first crimp piece 15 and the second crimp piece 16 are formed at positions that are offset relative to the synthetic resin material 11, and are crimped at positions that deviate in the length direction relative to the synthetic resin material 11.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

### LIST OF REFERENCE NUMERALS

10 Metal plate
11 Synthetic resin material
12 Fixing structure
13 Wiring member
14 Bottom wall
15 First crimp piece (crimp piece)
16 Second crimp piece (crimp piece)
18 First crimped portion (crimped portion)
19 Second crimped portion (crimped portion)

1. A fixing structure for a metal plate and a synthetic resin material,
the metal plate having a bottom wall and a crimp piece that extends from a side edge of the bottom wall and is crimped so as to wind around the synthetic resin material, and
a recessed portion formed in the synthetic resin material serving as a crimped portion, with the crimp piece being crimped to the crimped portion.

2. The fixing structure for a metal plate and a synthetic resin material according to claim 1, wherein
the crimp piece is crimp pieces respectively extending from opposite side edges of the bottom wall, and
the crimp pieces are crimped to the crimped portion of the synthetic resin material such that distal end edges of the crimp pieces are opposed to each other.

3. The fixing structure for a metal plate and a synthetic resin material according to claim 2, wherein
the crimped portion is constituted by opposite side edges of the synthetic resin material being depressed, and
Expressions (1) and (2) below are satisfied:
PW1<MW3<PW1+PD1+PD2 (1)
MH1=MH2 (2)
where PD1 is a depression depth dimension of the crimped portion, among the crimped portions, that is formed at one side edge of the synthetic resin material, from the side edge of the synthetic resin material,
PD2 is a depression depth dimension of the crimped portion, among the crimped portions, that is formed at the other side edge of the synthetic resin material, from the side edge of the synthetic resin material,
PW1 is a width dimension of a region of the synthetic resin material that is sandwiched between the crimped portions,
MH1 is an extension height dimension of the crimp piece, among the crimp pieces, that is formed at one side edge of the bottom wall, from the one side edge of the bottom wall, and MH2 is an extension height dimension of the crimp piece formed at the other side edge of the bottom wall, from the other side edge of the bottom wall,
MW1 is a width dimension of the crimp piece, among the crimp pieces, that is formed at one side edge of the bottom wall, in a direction intersecting a direction extending from the one side edge of the bottom wall,
MW2 is a width dimension of the crimp piece formed at the other side edge of the bottom wall, in a direction intersecting a direction extending from the other side edge of the bottom wall, and
MW3 is a width dimension of the bottom wall.

4. The fixing structure for a metal plate and a synthetic resin material according to claim 3, wherein
Expression (3) below is satisfied:
0.8≤H/(T1+T2×2)≤1.5 (3)
where T1 is a thickness dimension of the synthetic resin material,
T2 is a thickness dimension of the metal plate, and
H is a maximum height dimension from a bottom face of the bottom wall to the crimp pieces in a state in which the crimp pieces are crimped to the crimped portions.

5. The fixing structure for a metal plate and a synthetic resin material according to claim 4, wherein
Expression (4) below is satisfied:
0.8≤H/(T1+T2×2)≤1.3 (4)

6. The fixing structure for a metal plate and a synthetic resin material according to claim 5, wherein
Expression (5) below is satisfied:
0.8≤H/(T1+T2×2)≤1.2 (5)

7. A wiring member including a metal plate that is to be connected to an electrical device, comprising:
the fixing structure for a metal plate and a synthetic resin material according to claim 1.
